(19) United States
(12) Patent Application Publication
(10) Pub. No.: US 2003/0003723 A1
(43) Pub. Date: Jan. 2, 2003

(54) Method for manufacturing semiconductor device

(76) Inventor: Wan-Gyu Lee, Ichon-shi (KR)

Correspondence Address: JACOBSON HOLMAN, PROFESSIONAL LIMITED LIABILITY COMPANY, 400 SEVENTH STREET, N.W., WASHINGTON, DC, 20004, US

(21) Appl. No.: 09/964,527

(22) Filed: Sep. 28, 2001

(30) Foreign Application Priority Data
Jun. 30, 2001 (KR) 2001-38692

(51) Int. Cl. H01L 21/8238

(52) U.S. Cl. 438/664; 438/655

(57) ABSTRACT

Disclosed is a method for manufacturing semiconductor device capable of performing a low resistance in a self-align TiSi₂. The method for manufacturing semiconductor device includes the steps of: a) forming a semiconductor layer including a silicon layer formed on a portion of a semiconductor substrate; b) forming a Ti layer and a TiN layer on the semiconductor layer; c) applying a first thermal treatment to the Ti layer for forming a TiSi₂ layer on the semiconductor layer; d) after forming the TiSi₂ layer, removing a Ti layer and the TiN layer which are not reacted; and e) applying a second thermal treatment to the TiSi₂ layer for phase transition of the TiSi₂ layer.

### FIELD OF THE INVENTION

The present invention relates to a method for manufacturing semiconductor device; and, more particularly, to a method for manufacturing semiconductor device capable of obtaining a low resistance in a self-align TiSi₂.

### DESCRIPTION OF THE PRIOR ART

Recently, in a method for manufacturing semiconductor device that requires a high integration and a high speed, researches for a low resistance of a connecting material has been proceeded for reducing a parasite resistance.

For example, in case of multilayer interconnection, a grain size of an Al becomes larger and is highly orientated to guarantee the reliability of metal wires. Meanwhile, a Cu material is considered as a metal interconnection, instead of Al material, to guarantee the reliability and to realize low resistance. In case of conductive metal wires, such as a gate electrode and a bit line, silicide layers using Ti, Co and Ni are employed as metal interconnection, instead of silicide layers which are formed by Mo and W, in order to carry out a low temperature process.

The above-mentioned silicide using Mo and W is hard to get low resistivity of below 80 μΩcm at a temperature of below 800° C. However, in a TiSi₂ layer of a C54 phase, it is possible to obtain low resistivity of about 13 to 20 μΩcm.

More specifically, the TiSi₂ layer can exist as an orthorhombic base-centered phase (hereinafter, referred to as a C49 phase) which has high resistivity of about 30 to 60 μΩcm and as an orthorhombic face-centered phase (hereinafter, referred to as a C54 phase) which is stabilized in thermal dynamics and has low resistivity of about 12 to 20 μΩcm.

FIGS. 1A to 1C are cross-sectional views illustrating a conventional TiSi₂ layer manufacturing method.

Referring to FIG. 1A, a field oxide layer 12 which isolates between devices is formed on a semiconductor substrate 11, and a gate oxide layer 13 and a gate electrode 14 are successively formed on the semiconductor substrate 11. At this time, the gate electrode 14 may be a polysilicon layer, a metal layer or a stacked layer of a polysilicon and a metal layer, and preferably a polysilicon layer is used as a single layer.

Subsequently, a low concentration diffusion layer 15 is formed in the semiconductor substrate 11 through a light dopant ion injection by using the gate electrode 14 as a mask, and a sidewall spacers 16, which are in contact with sidewalls of the gate electrode 14, are formed by depositing an insulating layer on the resulting structure and by etching back the insulating layer.

A high concentration diffusion layer 17 that is connected to the low concentration diffusion layer 15 is formed through high dopant ion injection by using the gate electrode 14 and the sidewall spacers 16 as a mask. Where, the low concentration diffusion layer 15 is referred to as a lightly doped drain (LDD) and the high density dopant diffusion layer 17 is usually called as a source/drain.

A Ti layer 18 is deposited on the resulting structure by using a physical vapor deposition (EVD) at a temperature of about 400° C.

Referring to FIG. 1B, an unstable C49 phase TiSi₂ layers 19 are formed through Ti diffusion from the Ti layer 18 to the silicon layers including the gate electrode 14 and a source/drain 17, which is caused by carrying out a rapid thermal process (RTP) in a nitrogen atmosphere. However, the C49 phase TiSi₂ layer 19 has high resistivity of about 30 to 60 μΩcm because a phase transition to a C54 phase is not performed yet.

Referring to FIG. 1C, the C49 phase TiSi₂ layer 19 is phase transited to a C54 phase TiSi₂ layer 19a, which is stable and has a low resistance, by carrying out the thermal treatment again.

However, recently, with a high integration of a semiconductor device, the width of the gate electrode and the diffusion layer is getting narrower so that it is difficult to achieve a phase transition from a C49 phase TiSi₂ of high resistance to a C54 phase TiSi₂ of low resistance.

The reason is that, with downsizing of a semiconductor device and reducing a gate line width, so a nuclear formation in a C54 phase, which is generated within C49 phase TiSi₂ layer by reacting the titanium layer on the silicon layer, is difficult. Since a nuclear formation of the C54 phase is generated at a grain boundary which is formed by gathering three grains, the number of nuclears of the C54 phase per unit area is differentiated in sizes of the grains.

As described above, the size of the grain of C49 phase, which is formed on a top portion of a gate by reacting the Ti layer and the polysilicon layer, is over 0.20 μm. Therefore, if a line width of the gate electrode is below 0.25 μm, the number of nuclears of the C54 phase formed per unit area is rapidly decreased.

With the reason, in a device which has a minimum line width of about 0.25 μm, the width of the Ti layer which is required in threshold nuclear formation to generate a phase transition, is larger than 0.25 μm, so that a phase change from C49 structure to C54 structure is not happened. Therefore, a resistance value of the TiSi₂ layer in a gate electrode and a dopant diffusion layer is rapidly increased.

To solve the above-mentioned problem, As ions are injected into the required areas, such as the gate electrode and the source/drain, before depositing the Ti layer in order to apply the pre-amorphization implatation (PAI) the diffusion layer and the gate electrode.

However, the PAI injects the As dopants into the diffusion layer, which has a dose of over 3×10¹⁴ atoms/cm², thereby reducing a reaction speed when the Ti thin layer reacts on the silicon layer in the silicide process.

Moreover, in a logic device, an amount of dopants and distribution within a polysilicon gate electrode of an NMOS transistor are changed by the PAI using the As dopants. Therefore, in a device which has a line width lower than 0.25 μm, a characteristic thereof is changed and it is also differentiated according to a wafer location.

Besides the As ions, a high concentration diffusion layer, specifically, other ions injected to a source/drain of an N-channel metal oxide semiconductor (NMOS) transistor generally decrease a diffusion speed of a silicon atom, thereby to decrease the reaction speed of the silicide process.

Therefore, a thickness of the TiSi₂ layer formed in an NMOS transistor is getting thinner by ions that are injected to a source/drain and injected for PAI.

Besides, a nitride gas used in the RTP is also preventing the TiSi₂ nuclear formation and it makes thinner a thickness of the TiSi₂ layer, thereby to increase a resistance than a TiSi₂ layer of a PMOS transistor.

Also, in a post thermal treatment process, the TiSi₂ layer, which has a thinner thickness, is thermally unstable as the thickness is thinner and easily coheres so that the TiSi₂ layer is easily cut with more increase of the its resistance.

### SUMMARY OF THE INVENTION

It is, therefore, an object of the present invention to provide a method for manufacturing semiconductor device capable of preventing high resistance from being caused by a thickness reduction of a TiSi₂ layer and guaranteeing a thermal stable from cohesion or cutting of a TiSi₂ layer in a post thermal process.

In accordance with an aspect of the present invention, there is provided a method for manufacturing semiconductor device, comprising steps of: a) forming a semiconductor layer including a silicon layer formed on a portion of a semiconductor substrate; b) forming a Ti layer and a TiN layer on the semiconductor layer; c) applying a first thermal treatment to the Ti layer for forming a TiSi₂ layer on the semiconductor layer; d) after forming the TiSi₂ layer, removing a Ti layer and the TiN layer which are not reacted; and e) applying a second thermal treatment to the TiSi₂ layer for phase transition of the TiSi₂ layer.

Preferably, according to the present invention, the Ti layer is deposited by using a physical vapor deposition (PVD), and the TiN layer formed on the Ti layer is formed by using the PVD with the same vacuum chamber.

### BRIEF DESCRIPTION OF THE DRAWINGS

Other objects and aspects of the invention will become apparent from the following description of the embodiments with reference to the accompanying drawings, in which:

FIGS. 1A to 1C are cross-sectional views illustrating a conventional method for manufacturing semiconductor device; and

FIGS. 2A to 2C are cross-sectional views showing a method for manufacturing semiconductor device in accordance with the present invention.

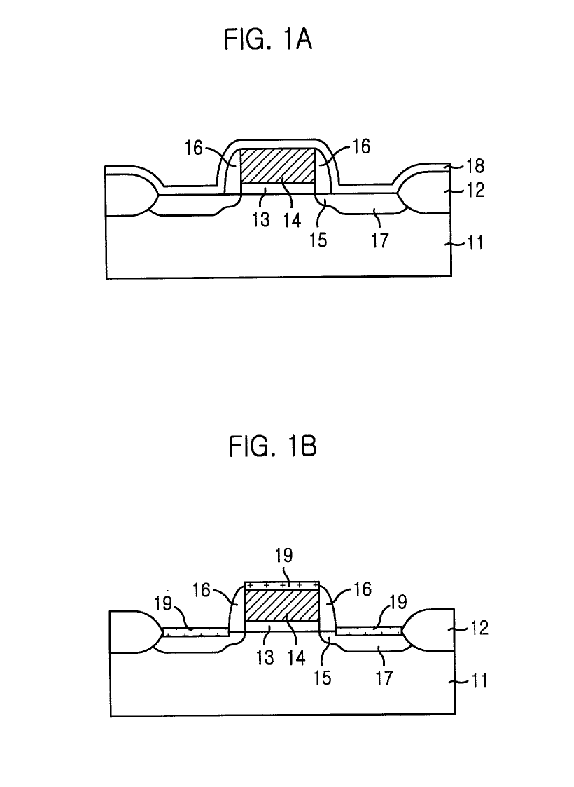

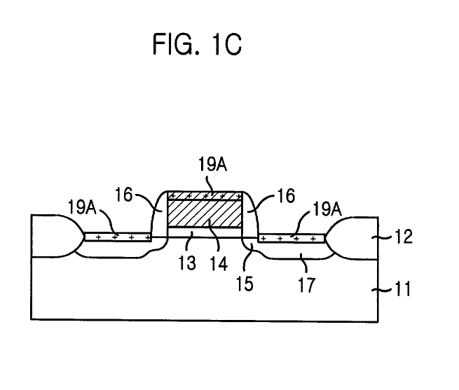

### DETAILED DESCRIPTION OF THE PREFERRED EMBODIMENTS

Hereinafter, a method for manufacturing semiconductor device according to the present invention will be described in detail referring to the accompanying drawings.

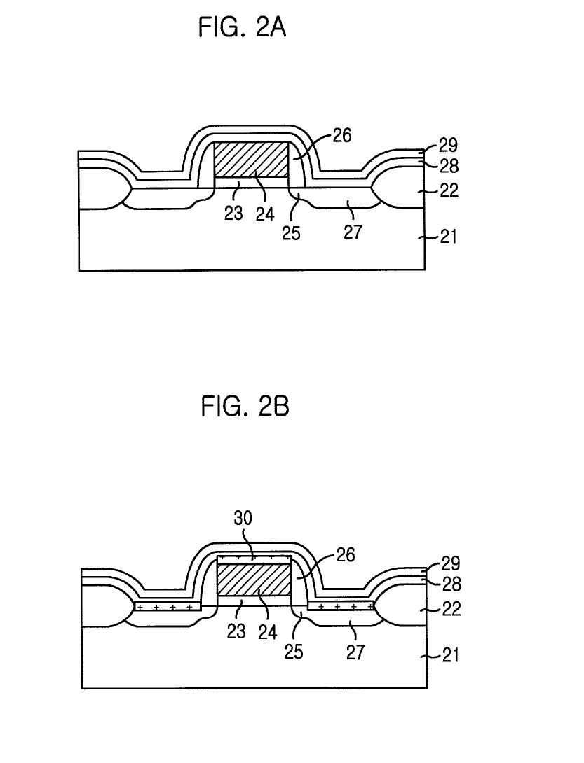

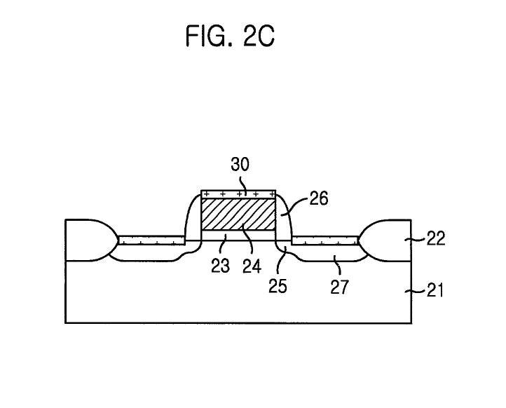

FIGS. 2A to 2C are cross-sectional views showing a method for manufacturing semiconductor device in accordance with the present invention. An N-channel metal oxide semiconductor (NMOS) transistor is only described among a CMOS manufacturing process.

Referring to FIG. 2A, a filed oxide layer 22 is formed on a semiconductor substrate 21 to isolate between devices, and a gate oxide layer 23 and a gate electrode 24 are successively formed on the semiconductor substrate 21. At this time, the gate electrode 24 may be a stacked layer of a metal or polysilicon layer and a metal layer, and a single layer of polysilicon layer.

Next, an N⁻ diffusion layer 25, which is a lightly doped drain (LDD) region, is formed in the semiconductor substrate 21 through a low concentration ion injection by using the gate electrode 24 as an ion blocking layer. Subsequently, an insulating layer is deposited on the resulting structure and a blanket etching is carried out to form sidewall spacers 26, which are in connect with sidewalls of the gate electrode 24.

An N⁺ dopant diffusion layer 27, which is connected to the N− dopant diffusion layer 25, is formed through a high concentration ion injection by using the gate electrode 24 and the sidewall spacers 26 as an ion blocking mask. At this time, in case of forming the N⁺ dopant diffusion layer 27, As ions are injected. Also, in case of a PMOS transistor (not shown), a P⁺ dopant diffusion layer may be formed through an ion injection of boron (B) or BF₂ ions in a predetermined portion of the semiconductor substrate 21.

After the N⁺ dopant diffusion layer 27 is formed, a first thermal process is carried out in an atmosphere of any one selected from the group consisting of NH₃, N₂ and Ar gas, thereby activating dopants'diffusion into the N⁺ dopant diffusion layer 27.

At this time, the first thermal process is carried out at a temperature of approximately 950° C. to 1050° C. and for about 30 to 40 seconds, by using a rapid thermal process (RTP) device at a nitrogen atmosphere.

First and second metal layers are successively deposited in the resulting structure of the semiconductor substrate 21. First, a Ti layer 28 is deposited at a thickness of about 200 Å to 450 Å and then a TiN layer 29 is deposited at a thickness of about 50 Å to 120 Å.

The Ti layer 28 deposition is carried out at a temperature of about 100° C. to 400° C. and for about a few seconds within a physical vapor deposition (PVD) chamber. The deposition of the TiN layer 29 is carried out at a temperature of below 100° C. to 400° C. and for about a few seconds within another chamber of the same physical vapor deposition (PVD) chamber.

If the TiN layer 29 is deposited over a thickness of 120 Å, a lot of time is required to remove it in the following removing process. The TiN layer 29 is deposited for the purpose of preventing a diffusion of a nitride gas at the time forming a TiSi₂ layer in the subsequent process, so it may not be deposited over a thickness of 120 Å.

When the Ti layer 28 and the TiN layer 29 are formed, the heat temperature of the semiconductor substrate is preferably carried out at a temperature, which provides the lowest resistance.

As described above, the TiN layer 29 is deposited on the Ti layer 28 to prevent exposure of the Ti layer 28 before a rapid thermal treatment for forming a silicide layer so that the Ti 28 layer is protected from a native oxide layer formation followed by a long period exposure a dopant generating.

Referring to FIG. 2B, after the Ti layer 28 and the TiN 29 layer are deposited at a predetermined sequence. Therefore, the increase of the thickness of the TiN layer 29 has an effect on the formation of the TiSi₂ layer. The additionally formed TiN layer prevents the nitrogen gas from diffusing into the Ti layer 28 at the thermal process in the nitrogen atmosphere, thereby to guarantee the formation of the predetermined TiSi₂ layer.

TiSi₂ layers 30 are formed on an upper portion of an N⁺ dopant diffusion layer 27 and a gate electrode 24. Therefore, the increase of the thickness of the TiN layer 29 has an effect on the formation of the TiSi₂ layer. The additionally formed TiN layer prevents the nitrogen gas from diffusing into the Ti layer 28 at the thermal process in the nitrogen atmosphere, thereby to guarantee the formation of the predetermined TiSi₂ layer. This second thermal process is carried out at a temperature of about 650° C. to 715° C., about 10 to 30 seconds.

As described above, the TiSi₂ layers 30 formed by the second thermal process are formed at a thickness of about 380 Å to 850 Å by reacting the Ti 28 layer on the Si layer of the N⁺ dopant diffusion layer 27 and the gate electrode 24. At this time, a non-reacted Ti layer 28 is remnant on the sidewall spacers 16 and the field oxide layer. Also, since a predetermined thickness of Ti is activated, a non-reacted Ti layer may be remnant on the TiSi₂ layer. Since the second thermal process is carried out at a temperature of about 650° C. to 715° C., the TiSi₂ layer has an unstable C49 phase and high resistivity.

Besides, when the TiSi₂ layer 30 is formed through a thermal process at a nitrogen atmosphere, additional TiN layer is formed so that a thickness of the TiN layer 29 is slightly increased. Therefore, the increase of the thickness of the TiN layer 29 has an effect on the formation of the TiSi₂ layer. The additionally formed TiN layer prevents the nitrogen gas from diffusing into the Ti layer 28 at the thermal process in the nitrogen atmosphere, thereby to guarantee the formation of the predetermined TiSi₂ layer.

As a result, since the increase of the thickness of the TiN layer 29 prevents the diffusion of the nitrogen gas, the TiSi₂ layer 30 is formed with a sufficient thickness without a loss of the silicide layer. In the CMOS technique, the TiSi₂ layer may have the same thickness in the NMOS and PMOS transistors.

Referring to FIG. 2C, the non-reacted Ti layer 28 and TiN layer 29, which are not associated with the silicide reaction, are removed and a third thermal process is carried out. At this time, the third thermal process is carried out at a temperature of about 800° C. to 850° C. and for about 10 to 30 seconds, and the C49 phase, which is formed by the second thermal treatment, is phase transited to a stable C59 phase, thereby reducing resistivity of the TiSi₂ layer.

Meanwhile, when removing the non-reacted Ti layer 28 and the TiN layer 29, a wet etching is used and using a mixed solution of NH₄OH:H₂O₂:H₂O at a ratio of 1:1:5.

Typically, when the TiSi₂ layer is formed without a pre-amorphization implantation (PAI) in accordance with an embodiment of the present invention, the thickness of the TiSi₂ layer is increased from 400 Å to 480 Å, comparing the TiSi₂ layer formed by the PAI. Also, resistance is decreased from 4.4 Ω/□ to 3.3 Ω/□.

The above-mentioned self-aligned TiSi₂ manufacturing method may deposit the TiSi₂ layer in a same thickness in NMOS and PMOS transistors by using the TiN layer, thereby preventing low resistivity and cohesion and a cutting through increased thickness of the TiSi₂ layer in a post thermal process so that a device yield and operation characteristic may be also improved.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing semiconductor device, comprising steps of:
a) forming a semiconductor layer including a silicon layer formed on a portion of a semiconductor substrate;
b) forming ion injection region by injecting dopants into the semiconductor substrate
c) forming a Ti layer and a TiN layer on the semiconductor layer;
d) applying a first thermal treatment to the Ti layer for forming a TiSi₂ layer on the semiconductor layer;
e) after forming the TiSi₂ layer, removing a Ti layer and the TiN layer which are not reacted; and
f) applying a second thermal treatment to the TiSi₂ layer for phase transition of the TiSi₂ layer.

2. The method of claim 1, wherein the step c) includes the steps of:
c1) depositing the Ti layer by using a physical vapor deposition (PVD); and
c2) depositing the TiN layer on the Ti layer by using a physical vapor deposition (PVD).

3. The method of claim 1, wherein the first and the second thermal treatment are carried out by any one selected from the group consisting of NH₃, N₂ and Ar gas.

4. The method of claim 1, wherein the first thermal treatment is carried out at a temperature of about 650° C. to 715° C. and for about 10 to 30 seconds.

5. The method of claim 1, wherein the Ti layer is formed at a thickness of about 200 Å to 450 Å.

6. The method of claim 1, wherein the TiN layer is formed at a thickness of about 50 Å to 120 Å.

7. The method of claim 1, wherein the second thermal treatment is carried out at a temperature of about 800° C. to 850° C. and for about 10 to 30 seconds.

8. The method of claim 1, wherein the step b) includes a step of activating the dopants to form a dopant diffusion layer by using a thermal treatment at a temperature of 950° C. to 1050° C.

9. The method of claim 1, wherein the step d) is carried out by a wet etching using a mixed solution of NH₄OH:H₂O₂:H₂O.

10. The method of claim 1, wherein the semiconductor layer includes a gate electrode and source/drain regions of a transistor.
